(19) United States
(12) Patent Application Publication
(10) Pub. No.: US 2026/0354090 A1
(43) Pub. Date: Nov. 5, 2026

(54) INSULATION ENCAPSULATION TO PREVENT OUTGASSING AND CONTAMINATION

(71) Applicant: KLA Corporation, Milpitas, CA (US)

(72) Inventors: Farhat A. Quli, Castro Valley, CA (US); Razieh Mahzoon, Fremont, CA (US)

(21) Appl. No.: 19/194,739

(22) Filed: Apr. 30, 2025

(51) Int. Cl. H10P 72/00; G01K 1/14; G01K 7/02; H05K 5/00; H05K 5/03; H05K 7/14

(52) U.S. Cl. CPC H10P 72/0602; G01K 1/14; G01K 7/02; H05K 5/0069; H05K 5/03; H05K 7/1427

(57) ABSTRACT

A film-based encapsulation may encapsulate insulation to enable the use of porous insulation in applications where the insulation is subject to contamination and/or vacuum. Porous insulations have extremely low thermal conductivity at atmospheric pressure and at low pressure. The porous insulations are excellent candidates for insulating delicate electronic components and power sources from high process temperatures that sensor wafers are used to monitor. However, the porous nature makes working with these materials difficult. The porous insulation may be pre-encapsulated into manageable sections. Alternately, the insulation and insulated components can be pre-encapsulated together. These pre-encapsulated elements can then be integrated into the sensor wafer.

### TECHNICAL FIELD

The present disclosure generally relates to monitoring of wafers along a semiconductor process line, and more particularly to process condition monitoring wafers.

### BACKGROUND

As tolerances on process conditions in semiconductor device processing environments continue to narrow, the demand for improved process monitoring systems continues to increase. Thermal uniformity within a processing system (e.g., epitaxy chamber) is one such condition. Current methods may be unable to monitor temperature under the extreme conditions (e.g., high temperature) required of current processing techniques without contaminating the associated chamber. Therefore, it would be desirable to provide a system and method to allow for high temperature measurement using an instrumented wafer to monitor the conditions of a semiconductor device processing line.

### SUMMARY

A process condition measurement device is described, in accordance with one or more embodiments of the present disclosure. The process condition measurement device may include: a substrate assembly including a bottom substrate and a top substrate; a conductive trace, wherein the conductive trace is formed on or embedded in the bottom substrate, wherein the top substrate is disposed over and covers the conductive trace; a lid defining a cavity; an adhesive; and an enclosure assembly, wherein the lid is disposed above and covers the enclosure assembly and the adhesive, wherein the enclosure assembly is adhered within the cavity by the adhesive, wherein the enclosure assembly includes: a component package, an inner enclosure, wherein the inner enclosure encloses the component package; an electrical connection, wherein the electrical connection connects between the conductive trace and the component package by passing into the inner enclosure; a porous insulation, wherein the porous insulation includes at least a top insulation layer and a bottom insulation layer, wherein the inner enclosure is disposed between the top insulation layer and the bottom insulation layer, a film-based encapsulation, wherein the film-based encapsulation encapsulates the porous insulation, and a joint, wherein the joint joins the film-based encapsulation around the porous insulation.

A system is described, in accordance with one or more embodiments of the present disclosure. The system may include: a process condition measurement device including: a substrate assembly including a bottom substrate and a top substrate; a conductive trace, wherein the conductive trace is formed on or embedded in the bottom substrate, wherein the top substrate is disposed over and covers the conductive trace; a lid defining a cavity; an adhesive; and an enclosure assembly, wherein the lid is disposed above and covers the enclosure assembly and the adhesive, wherein the enclosure assembly is adhered within the cavity by the adhesive, wherein the enclosure assembly includes: a component package, an inner enclosure, wherein the inner enclosure encloses the component package; an electrical connection, wherein the electrical connection connects between the conductive trace and the component package by passing into the inner enclosure; a porous insulation, wherein the porous insulation includes at least a top insulation layer and a bottom insulation layer, wherein the inner enclosure is disposed between the top insulation layer and the bottom insulation layer, a film-based encapsulation, wherein the film-based encapsulation encapsulates the porous insulation, and a joint, wherein the joint joins the film-based encapsulation around the porous insulation; and a front opening unified pod, wherein the front opening unified pod is configured to receive the process condition measurement device.

A method is described, in accordance with one or more embodiments of the present disclosure. The method may include: placing a top insulation layer, a side insulation layer, and a bottom insulation layer within respective of a top film-based encapsulation, a side film-based encapsulation, and a bottom film-based encapsulation; degassing the top insulation layer, the side insulation layer, and the bottom insulation layer, wherein the top insulation layer, the side insulation layer, and the bottom insulation layer are degassed by at least one of evacuation or heating; forming a top joint, a side joint, and a bottom joint to encapsulate the top insulation layer, the side insulation layer, and the bottom insulation layer within respective of the top film-based encapsulation, the side film-based encapsulation, and the bottom film-based encapsulation; and adhering a component package, an inner enclosure, the top film-based encapsulation, the side film-based encapsulation, and the bottom film-based encapsulation adhered within a cavity by an adhesive, wherein at least a lid of a process condition measurement device defines the cavity.

A method is described, in accordance with one or more embodiments of the present disclosure. The method may include: placing a component package, an inner enclosure, a top insulation layer, a side insulation layer, and a bottom insulation layer within a multi-layer film-based encapsulation; degassing the top insulation layer, the side insulation layer, and the bottom insulation layer, wherein the top insulation layer, the side insulation layer, and the bottom insulation layer are degassed by at least one of evacuation or heating; forming a joint to encapsulate the component package, the inner enclosure, the top insulation layer, the side insulation layer, and the bottom insulation layer within the multi-layer film-based encapsulation; and adhering the multi-layer film-based encapsulation within a cavity by an adhesive, wherein at least a lid of a process condition measurement device defines the cavity.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the description and drawings serve to explain the principles of the disclosure.

### BRIEF DESCRIPTION OF THE DRAWINGS

The numerous advantages of the disclosure may be better understood by those skilled in the art by reference to the accompanying figures in which:

FIG. 1 depicts a top view of a process condition measurement device with an enclosure assembly, in accordance with one or more embodiments of the present disclosure.

FIG. 2A depicts a cross-section view of the enclosure assembly with porous insulation layers which are encapsulated by top, side, and bottom film-based encapsulations, in accordance with one or more embodiments of the present disclosure.

FIGS. 2B-2C depict partial-exploded views of the enclosure assembly with porous insulation layers which are encapsulated by top, side, and bottom film-based encapsulations, in accordance with one or more embodiments of the present disclosure.

FIG. 3 depicts a cross-section view of the enclosure assembly with porous insulation layers and a component package which are encapsulated by a multi-layer film-based encapsulation, in accordance with one or more embodiments of the present disclosure.

FIG. 4 depicts a simplified block diagram of a system with the process condition measurement device, in accordance with one or more embodiments of the present disclosure.

FIG. 5 depicts a cross-section view of the enclosure assembly supported on top of a top substrate, in accordance with one or more embodiments of the present disclosure.

FIG. 6-7 depict flow diagrams of methods of manufacturing the enclosure assembly, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to insulation encapsulation to prevent outgassing and contamination. A film-based encapsulation may encapsulate insulation to enable the use of porous insulation in applications where the insulation is subject to contamination and/or vacuum. Porous insulations have extremely low thermal conductivity at atmospheric pressure and at low pressure. The porous insulations are excellent candidates for insulating delicate electronic components and power sources from high process temperatures that sensor wafers are used to monitor. However, the porous nature makes working with these materials difficult. The porous insulation may be pre-encapsulated into manageable sections. Alternately, the insulation and insulated components can be pre-encapsulated together. These pre-encapsulated elements can then be integrated into the sensor wafer.

U.S. Patent Publication Number 2022/0189803, titled “Sensor configuration for process condition measuring devices”; U.S. Patent Publication Number 2024/0274401, titled “Substrate position monitoring devices”; U.S. Patent Publication Number 2025/0054789A1, titled “Method of fabrication and implementation of process condition measurement device”; U.S. Pat. No. 7,855,549, titled “Integrated process condition sensing wafer and data analysis system”; U.S. Pat. No. 8,104,342, titled “Process condition measuring device”; U.S. Pat. No. 8,604,361, titled “Component package for maintaining safe operating temperature of components”; U.S. Pat. No. 8,681,493, titled “Heat shield module for substrate-like metrology device”; U.S. Pat. No. 9,222,842, titled “High temperature sensor wafer for in-situ measurements in active plasma”; U.S. Pat. No. 9,356,822, titled “Automated interface apparatus and method for use in semiconductor wafer handling systems”; U.S. Pat. No. 9,719,867, titled “Method And System For Measuring Heat Flux”; U.S. Pat. No. 10,215,626, titled “Method and system for measuring radiation and temperature exposure of wafers along a fabrication process line”; U.S. Pat. No. 10,460,966, titled “Encapsulated instrumented substrate apparatus for acquiring measurement parameters in high temperature process applications”; U.S. Pat. No. 10,720,350, titled “Etch-resistant coating on sensor wafers for in-situ measurement”; U.S. Pat. No. 11,150,140, titled “Instrumented substrate apparatus for acquiring measurement parameters in high temperature process applications”; U.S. Pat. No. 11,315,811, titled “Process Temperature Measurement Device Fabrication Techniques and Methods of Calibration and Data Interpolation of the Same”; U.S. Pat. No. 11,569,138, titled “System and method for monitoring parameters of a semiconductor factory automation system”; U.S. Pat. No. 11,668,601, titled “Instrumented substrate apparatus”; U.S. Pat. No. 11,784,071, titled “Process temperature measurement device fabrication techniques and methods of calibration and data interpolation of the same”; U.S. Pat. No. 11,823,925, titled “Encapsulated instrumented substrate apparatus for acquiring measurement parameters in high temperature process applications”; are each incorporated herein by reference in the entirety.

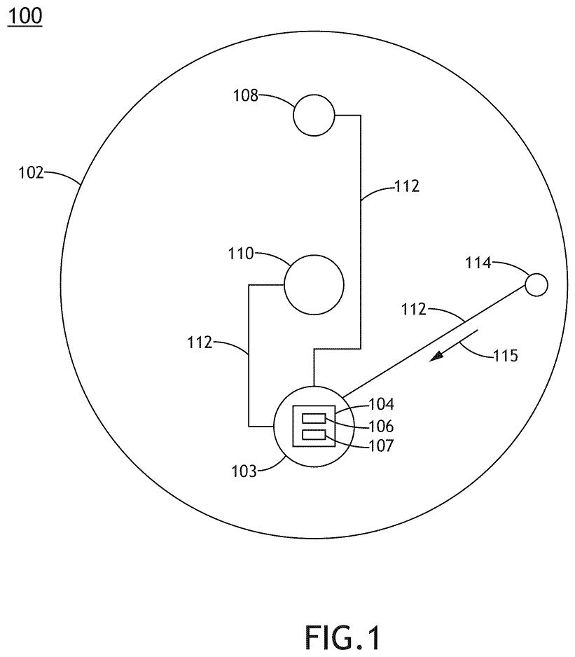

FIG. 1 depicts a process condition measurement device 100 (PCMD), in accordance with one or more embodiments of the present disclosure. The process condition measurement device 100 may be an instrumented substrate assembly, substrate device, instrumented wafer, instrumented wafer substrate, sensor wafer, substrate monitoring device, instrumented substrate device, inspection substrate, inspection wafer, measurement wafer, registration measuring substrate, registration wafer, and the like.

The process condition measurement device 100 may include one or more components, such as, but not limited to, a substrate assembly 102, an enclosure assembly 103, a controller 104, processors 106, memory 107, a power source 108, a communication interface 110, conductive traces 112, and/or sensors 114.

The substrate assembly 102 may include any substrate material. For example, the substrate assembly 102 may include a wafer. For example, the substrate assembly 102 may include a wafer structure formed from silicon (e.g., single crystal silicon), silicon carbide, silicon nitride, silicon dioxide (e.g., quartz), doped (e.g., n-type or p-type) silicon, glass (e.g., fused silica glass wafer, borosilicate glass wafer, and the like), carbon fiber stabilized epoxy matrices, one or more ceramic materials, glass carbon fibers, one or more composite materials, or a combination thereof. For example, the substrate assembly 102 may be formed from a composite material including two or more layers of material that may be bonded together or two or more materials that may be intermixed in a single layer or multiple layers. The substrate assembly 102 may also be a composite material such as graphite/epoxy or a laminate formed from silicon, graphite/epoxy, silicon. The substrate assembly 102 may be made of the same or similar materials to a production substrate.

The substrate assembly 102 may take on the same, or similar, size and shape as a standard substrate processed by a semiconductor device processing system. The substrate assembly 102 may have physical parameters that approximate the physical parameters of a production substrate used in the manufacture of integrated circuits or other electronics. The substrate assembly 102 may have dimensions conforming to that of a Semiconductor Equipment and Materials International (SEMI®) wafer. The substrate assembly 102 may include a round substrate (e.g., a round wafer) having a selected diameter. For example, the substrate assembly 102 may have a diameter between 25 and 450 mm, such as, but not limited to, 25 mm, 50 mm, 75 mm, 100 mm, 125 mm, 150 mm, 200 mm, 300 mm, or 450 mm. For instance, the substrate assembly 102 may include a diameter between 100 and 300 mm. Additionally, the substrate assembly 102 may have a thickness between 0.275 and 2 mm (e.g., 1.4 mm). The thickness may be based on the diameter. The substrate assembly 102 may also have a thickness that approximates the corresponding thickness of the production substrate, although the thickness may be slightly larger than the production substrate to accommodate additional electronics and/or other components of the process condition measurement device 100. The substrate assembly 102 may also be a glass-like rectangular reticle.

The substrate assembly 102 may include a top surface and/or a bottom surface. The top surface and/or the bottom surface of the substrate assembly 102 may be planar. It is further contemplated that the top surface may be non-planar while the bottom surface may be planar. The bottom surface may also be referred to as a backside.

One or more components of the process condition measurement device 100 may be disposed on the top surface and/or the bottom surface of the substrate assembly 102. For example, the enclosure assembly 103, the controller 104, the processors 106, the memory 107, the power source 108, the communication interface 110, the conductive traces 112, and/or the sensors 114 may be disposed on the substrate assembly 102. Any of the various components of the process condition measurement device 100 may be disposed on and/or embedded in the substrate assembly 102. The components of the process condition measurement device 100 may be disposed on the top surface. The substrate assembly 102 may define one or more cavities. The substrate assembly 102 may define one or more cavities in the top surface. The cavities may be defined by etching, precision grinding, or the like. Any of the various components of the process condition measurement device 100 may be embedded in the cavities, and thereby be embedded in the substrate assembly 102.

Any of the various components of the process condition measurement device 100 may be disposed at one or more locations on the substrate assembly 102. It is noted that the arrangement and number of the enclosure assembly 103, the controller 104, the processors 106, the memory 107, the power source 108, the communication interface 110, the conductive traces 112, and/or the sensors 114 depicted are not limiting and are provided merely for illustrated purposes. The enclosure assembly 103, the controller 104, the processors 106, the memory 107, the power source 108, the communication interface 110, the conductive traces 112, and/or the sensors 114 may be configured in several patterns, shapes, and quantities. One consideration in the location of the various components of the process condition measurement device 100 on the substrate assembly 102 may be to maintain a center of gravity of the process condition measurement device 100 at a center of the substrate assembly 102. The communication interface 110 may also be disposed at the center of the substrate assembly 102 to maintain communication regardless of the orientation of the process condition measurement device 100.

Any of the various components of the process condition measurement device 100 may be formed on or embedded in the substrate assembly 102 using any suitable technique. For example, the enclosure assembly 103, the controller 104, the processors 106, the memory 107, the power source 108, the communication interface 110, the conductive traces 112, and/or the sensors 114 may be formed on or embedded in the substrate assembly 102 via microelectromechanical system (MEMS) fabrication or semiconductor device fabrication techniques, such as, but not limited to, wet etching, dry etching, or electrical discharge machining.

The controller 104, the processors 106, the memory 107, the power source 108, the communication interface 110, and/or the sensors 114 may be electrically connected by the conductive traces 112. The conductive traces 112 may include any conductive material, such as, but not limited to, aluminum, copper, or the like. The conductive traces 112 may include flex circuits formed on or embedded in the substrate assembly 102 or fabricated discretely and embedded into the assembly.

The enclosure assembly 103 may include an electric circuit element or device, which it is necessary to thermally insulate. The enclosure assembly 103 may enclose one or more components of the process condition measurement device 100. For example, the enclosure assembly 103 may include the controller 104, the processors 106, the memory 107, the power source 108, the communication interface 110, and/or the sensors 114. As depicted, the enclosure assembly 103 includes the controller 104, although this is not intended to be limiting. The enclosure assembly 103 may also include the power source 108 and/or a high-heat capacity thermal mass.

The controller 104 may provide data collection and data storage functionality to the process condition measurement device 100. The controller 104 may be configured to send and/or receive data including, but not limited to, data from the communication interface 110 and/or the sensors 114. For example, the controller 104 may store sensor measurements 115 from the sensors 114.

The controller 104 may include processors 106 and memory 107. The memory 107 may store the processing conditions and program instructions for the operation of the process condition measurement device 100. The processors 106 may be configured to execute the program instructions maintained on the memory 107, the program instructions causing the processors 106 to execute any of the various process steps described.

The power source 108 may be a power supply. The power source 108 may include one or more batteries (e.g., rechargeable batteries), a wired power source, or the like. The power source 108 may provide power to any of the various components of the process condition measurement device 100. The power source 108 may optionally include one or more solar cells. The power source 108 may be embedded into the substrate assembly 102. The power source 108 may provide power storage functionality to the process condition measurement device 100.

The communication interface 110 may include a radio frequency (RF) inductive coil. The RF inductive coil may receive data and serves to inductively charge the power source 108. The communication interface 110 may also include a light emitting diode (LED) for transmitting data.

The communication interface 110 may include any wireline communication protocol (e.g., DSL-based interconnection, cable-based interconnection, T9-based interconnection, USB, and the like) or wireless communication protocol (e.g., GSM, GPRS, CDMA, EV-DO, EDGE, WiMAX, 3G, 4G, 4G LTE, 5G, Wi-Fi protocols, RF, Bluetooth, Intermediate System to Intermediate System (IS-IS), and the like). By way of another example, the communication interface 110 may include communication protocols including, but not limited to, radio frequency identification (RFID) protocols, open-sourced radio frequencies, and the like. By way of another example, the communication interface 110 may include inductive wireless communications and/or inductive wireless charging. For instance, the communication interface 110 may use On-Off keying and backscatter modulation for bidirectional data transfer together with inductive power transfer for battery charging. Accordingly, an interaction between the various devices may be determined based on one or more characteristics including, but not limited to, cellular signatures, IP addresses, MAC addresses, Bluetooth signatures, radio frequency identification (RFID) tags, and the like. The wireless communication may include wireless nearfield communication.

The sensors 114 may generate sensor measurements 115. The sensor measurements 115 may be generated by detecting one or more processing conditions.

Processing conditions may refer to various processing parameters used in manufacturing an integrated circuit. Processing conditions may include any parameter used to control semiconductor manufacture or any condition a manufacturer would desire to monitor such as, but not limited to, temperature, processing chamber pressure, gas flow rate within the chamber, gaseous chemical composition within the chamber, position within a chamber, ion current density, ion current energy, light energy density, and vibration and acceleration of a wafer or other substrate within a chamber or during movement to or from a chamber. Different processes will inevitably be developed over the years, and the processing conditions will, therefore, vary over time. Therefore, whatever the conditions may be, it is foreseen that the embodiments described will be able to measure such conditions.

The sensors 114 used for detecting various processing conditions may be mounted on or fabricated in substrate assembly 102 according to a semiconductor transducer design. The sensors 114 may include any discrete measurement device including, but not limited to, temperature sensors, pressure sensors, radiation sensors, chemical sensors, multi-axis accelerometers, multi-axis angular rate sensor, light sensors, barometric pressure sensors, capacitive sensors, time sensors, position sensors, dosage sensors, or a combination thereof. For example, the sensors 114 may include one or more temperature sensors configured to acquire one or more parameters indicative of temperature. For instance, the one or more temperature sensors may include, but are not limited to, one or more thermocouple (TC) devices (e.g., thermoelectric junction), one or more resistance temperature devices (RTDs) (e.g., thin film RTD), or the like. By way of another example, in the case of pressure measurements, the sensors 114 may include, but are not limited to, a piezoelectric sensor, a capacitive sensor, an optical sensor, a potentiometric sensor or the like. By way of another example, in the case of radiation measurements, the sensors 114 may include, but are not limited to, one or more light detectors (e.g., photovoltaic cell, photoresistor, and the like) or other radiation detectors (e.g., solid state detector). By way of another example, in the case of chemical measurements, the sensors 114 may include, but are not limited to, one or more chemiresistors, gas sensors, pH sensors, or the like. By way of another example, in the case of acceleration measurements, the multi-axis accelerometer may be an acceleration measuring type measuring 3-axis or 6-axis. By way of another example, in the case of rotation rates measurements, the multi-axis angular rate sensor may be a gyroscope. The multi-axis angular rate sensor may measure 3-axis rotation rates. By way of another example, in the case of light measurements, the light sensor may be a light measuring type with an excitation source. By way of another example, in the case of pressure measurements, the barometric pressure sensor may sense local barometric pressure of the process condition measurement device 100. By way of another example, in the case of capacitive measurements, the capacitive sensor may directly gauge a proximity of the process condition measurement device 100 relative to another component. By way of another example, in the case of time measurements, the time sensor may generate one or more time delay parameters. By way of another example, in the case of position measurements, the position sensors may be line sensors or the like. By way of another example, in the case of dosage measurements, the dosage sensors may be in-band dosage sensors, out-of-band dosage sensors, in-band scattered dosage sensors, or the like.

The sensors 114 may detect gradients in various processing conditions across the substrate assembly 102. The sensors 114 may be arranged in different areas (not depicted) on the surface or within substrate assembly 102 to measure the processing conditions across the substrate assembly 102. By measuring in different areas of the substrate assembly 102, the gradient across the substrate assembly 102 can be calculated, and additionally, the condition at a particular location on the substrate assembly 102 can be determined. The number of the sensors 114 in or on the substrate assembly 102 may vary depending upon the processing condition being measured and the size of the substrate assembly 102.

The controller 104 may be configured to calculate one or more values based on the sensor measurements 115. The controller 104 may be configured to calculate any value known in the art based on the sensor measurements 115. For example, in the case of temperature, the sensors 114 may be configured to generate thermocouple voltages (measurement parameters) indicative of temperature, and the controller 104 may be configured to calculate a temperature based on the thermocouple voltages. The controller 104 may be configured to send the sensor measurements 115 and/or the values calculated based on the sensor measurements 115 from the process condition measurement device 100 through the communication interface 110.

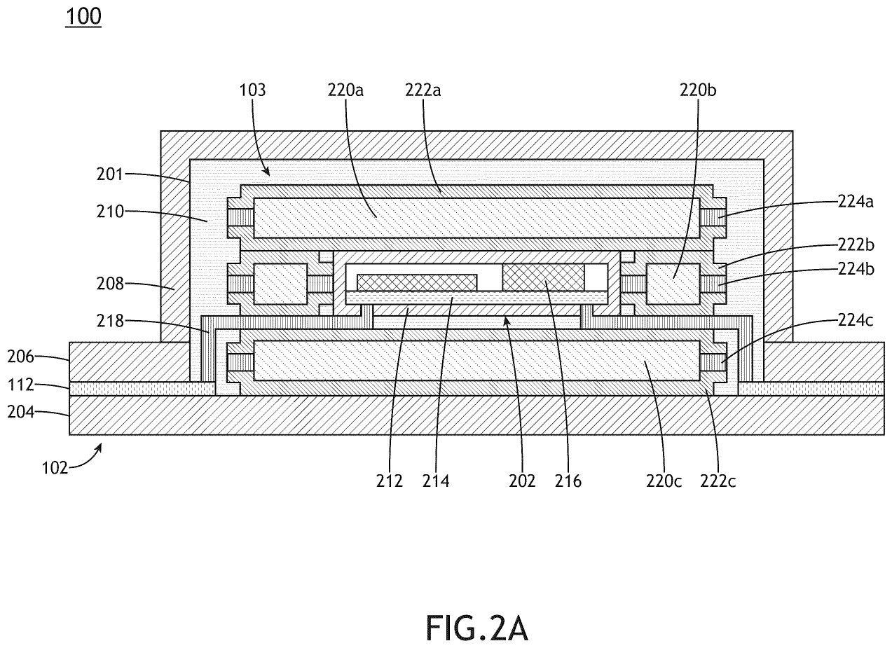

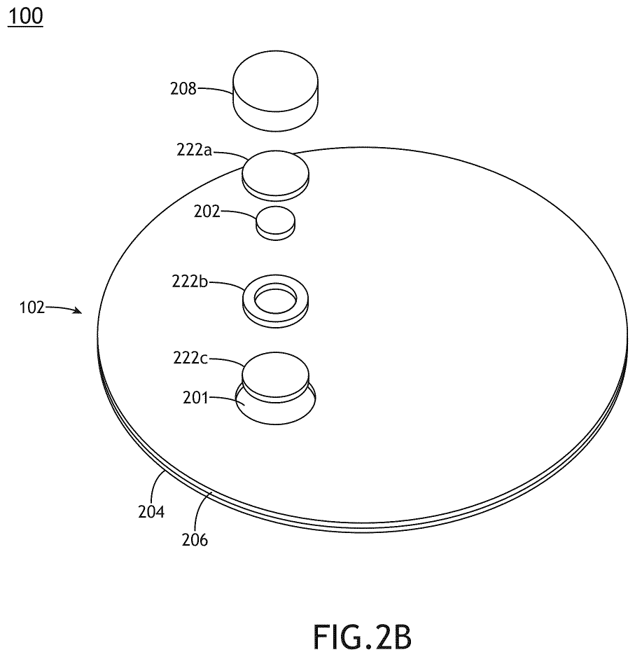

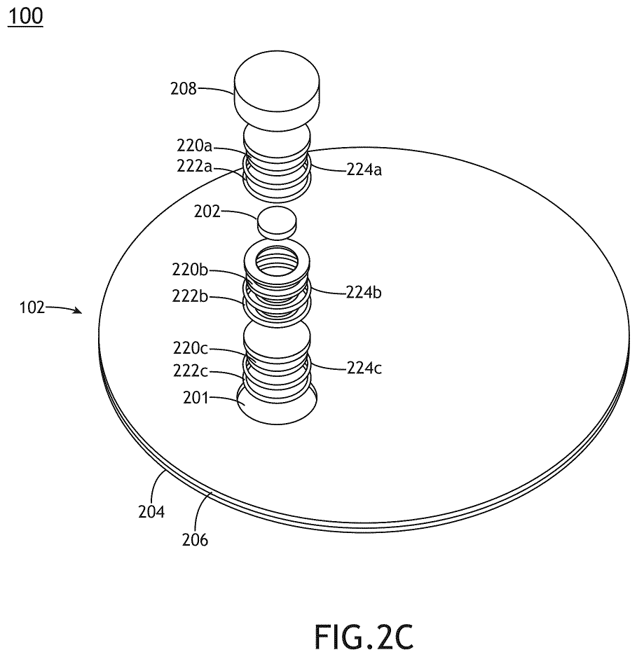

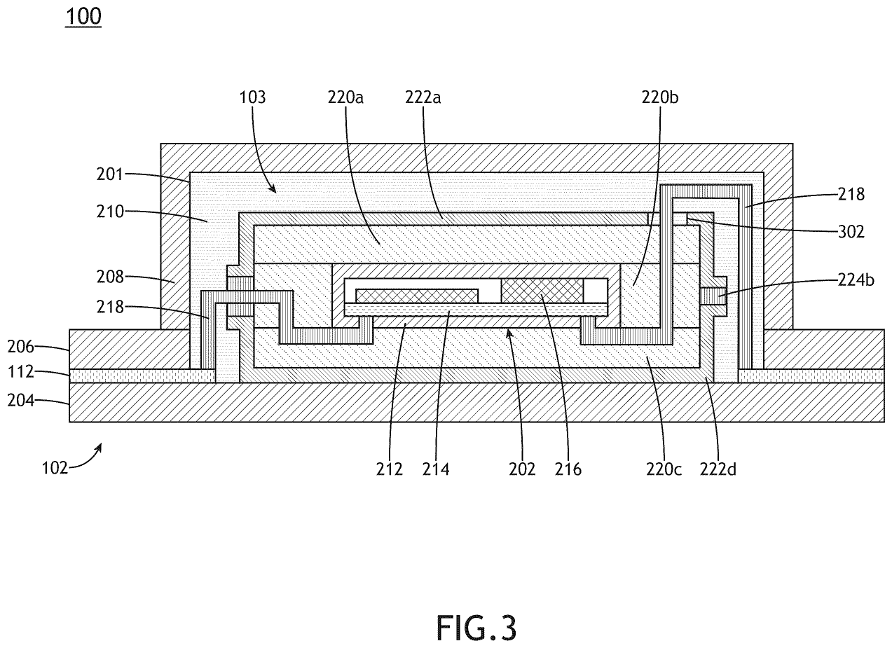

FIGS. 2A-3 depict the process condition measurement device 100, in accordance with one or more embodiments of the present disclosure. The process condition measurement device 100 may additionally include a bottom substrate 204, a top substrate 206, a lid 208, an adhesive 210, an inner enclosure 212, a printed circuit 214, die 216, electrical connection 218, porous insulation 220, film-based encapsulation 222, and/or joint 224.

The substrate assembly 102 may include the bottom substrate 204 and/or the top substrate 206. The bottom substrate 204 may be disposed below the top substrate 206. The top substrate 206 may be mechanically coupled to the bottom substrate 204. For example, the bottom substrate 204 and the top substrate 206 may be welded, direct bonded, adhered, or the like. The bottom substrate 204 and/or the top substrate 206 may include a same shape. For example, the bottom substrate 204 and/or the top substrate 206. The conductive traces 112 may be formed on or embedded in the bottom substrate 204. The top substrate 206 may be disposed over and cover the conductive traces 112. The top substrate 206 may protect the conductive traces 112 and prevent etching of the conductive traces 112 when subject to process conditions.

The top substrate 206 may be disposed between the bottom substrate 204 and the lid 208. The top substrate 206 may be disposed above the bottom substrate 204 and/or below the lid 208. The lid 208 may be disposed above the top substrate 206.

The bottom substrate 204, the top substrate 206, and/or the lid 208 may be made of any kind of substrate material, such as, but not limited to, silicon, glass, aluminum oxide, silicon carbide, quartz, and the like. In some embodiments, the bottom substrate 204 and/or the top substrate 206 of the process condition measurement device 100 may include a wafer. For example, the bottom substrate 204, the top substrate 206, and/or the lid 208 may be made of silicon. The bottom substrate 204, the top substrate 206, and/or the lid 208 may or may not be made of the same material. For example, each of the bottom substrate 204, the top substrate 206, and/or the lid 208 may be made of silicon. By way of another example, the bottom substrate 204 and the top substrate 206 may be made of silicon and the lid 208 may be made of a glass (e.g., an etch-resistant glass). The glass cover may resist etching. For example, the lid 208 may be formed from fused-silica. The lid 208 and/or top substrate 206 may additionally be coated with an etch resistant film (not depicted). The material properties of the bottom substrate 204, the top substrate 206, and/or the lid 208 may be selected to accommodate thermal expansion without cracking and/or warpage. For example, the bottom substrate 204, the top substrate 206, and/or the lid 208 may include a matching thermal expansion coefficient.

The lid 208 and top substrate 206 may be directly bonded. The lid 208 and top substrate 206 may be bonded directly through a direct bonding technique, such as direct silicon-to-silicon bonding, direct bonding through an oxide or hydroxide intermediary, eutectic bonding, anodic bonding, or the like. Bonding the lid 208 and the top substrate 206 directly may enable the lid 208 to protect the component package 202 as well as protect process chambers from contamination from the process condition measurement device 100.

The top substrate 206 and the bottom substrate 204 may also be directly bonded or bonded with an adhesive (not depicted). The top substrate 206 and bottom substrate 204 may themselves be composed of multiple bonded substrate layers prior to being bonded into the substrate assembly 102.

The lid 208 may be disposed above and cover the enclosure assembly 103 and the adhesive 210. The lid 208 may shield the enclosure assembly 103 and the adhesive 210 from EUV radiation or the like.

The lid 208 may be disposed above and partially cover the top substrate 206. The lid 208 may be smaller than the bottom substrate 204 and/or the top substrate 206. For example, the lid 208 may be a circle with a smaller diameter than the bottom substrate 204 and/or the top substrate 206. The lid 208 may provide a full cover to the component package 202 but only partially cover the bottom substrate 204 and/or the top substrate 206. It is contemplated that the lid 208 partially covering the top substrate 206 may be beneficial to reduce a weight of the process condition measurement device 100. The top surface of the process condition measurement device 100 may be non-planar where the lid 208 is the partial cover. For example, the top surface of the process condition measurement device 100 may include changes in height between the uncovered regions of the top substrate 206 and the lid 208. The lid 208 may be reduced in size to control the weight of the process condition measurement device 100 and/or the thickness in certain regions which do not include the lid 208.

The top substrate 206 and/or the lid 208 may define a cavity 201. The enclosure assembly 103 and/or the adhesive 210 may be disposed in the cavity 201 defined by the top substrate 206 and/or the lid 208 and covered by the lid 208. The cavity 201 may be defined by a through-hole in the top substrate 206 and a blind-hole in the lid 208. The cavity 201 may be defined through the top substrate 206 up to the bottom substrate 204. The enclosure assembly 103 may be supported by the surface of the bottom substrate 204 in the cavity 201. In this regard, the enclosure assembly 103 may be embedded within the substrate assembly 102. The enclosure assembly 103 may be embedded within the substrate assembly 102 to protect the enclosure assembly 103 from electrical and physical damage.

The cavity 201 may conform to the enclosure assembly 103. The cavity 201 the enclosure assembly 103 may include a selected shape. For example, the shape of the cavity 201 and the enclosure assembly 103 may be a cylinder, cuboid (e.g., a square cuboid), or the like. Conforming the cavity 201 to the enclosure assembly 103 may be beneficial to maintain a uniform spacing between the bottom substrate 204, the top substrate 206, and the lid 208 to the sides and top of the enclosure assembly 103. Conforming the cavity 201 to the enclosure assembly 103 may also reduce the amount of the adhesive 210 within the cavity 201.

The enclosure assembly 103 may be adhered within the cavity 201 by the adhesive 210. The enclosure assembly 103, the bottom substrate 204, the top substrate 206, and/or the lid 208 may be adhered by the adhesive 210. A bottom surface of the enclosure assembly 103 may be adhered to the bottom substrate 204 by the adhesive 210 or an additional adhesive (e.g., an adhesive film, not depicted). The adhesive 210 may be any kind of substrate adhesive, such as, but not limited to, silicone adhesive, epoxy adhesive, or the like. The adhesive 210 may be selected based on a thermal conductivity of the adhesive 210, to not imparting stress to the substrate assembly 102, and/or to not damage the component package 202 during curing. In addition to or instead of the adhesive 210 mentioned above, conductive adhesives may be used to electrically connect the bottom substrate 204 to the top substrate 206 and/or the lid 208. The adhesive 210 may be a cured adhesive. The adhesive 210 may be cured from a liquid adhesive to form the adhesive 210. The adhesive 210 may be cured by any suitable process, such as, but not limited to, drying, temperature, light curing (e.g., UV light curing), or the like. The adhesive 210 may be electrically resistive. The adhesive 210 may hermetically or near-hermetically seal the enclosure assembly 103. The adhesive 210 may provide a hermetic or near-hermetic seal between the lid 208 and the enclosure assembly 103. The hermetic seal may prevent fluid from flowing to and/or from the enclosure assembly 103. The near-hermetic seal may prevent substantially all of the fluid from flowing to and/or from the enclosure assembly 103.

The enclosure assembly 103 may include the component package 202, the inner enclosure 212, the printed circuit 214, the die 216, the electrical connection 218, the porous insulation 220, the film-based encapsulation 222, and/or the joint 224.

The component package 202 may include the printed circuit 214 and/or die 216. For example, the component package 202 may be a die-to-wafer stack, a ball-grid array package, a landing-grid array package, a 2.5D integration, a 3D integration, a chip-scale package, a system-in-package, a system on integrated chip, a multi-chip module, or the like. The component package 202 may include various connections, such as interconnections, hybrid bonds, bumps, pads, balls, through-silicon vias, or the like. The printed circuit 214 may include any printed circuit including, but not limited to, a printed circuit board, a printed wiring board, and the like. The printed circuit 214 may be formed from any printed circuit material art including, but not limited to, a ceramic, silicon, an inorganic material, and the like. The component package 202 may include any number of the die 216. The die 216 may be coupled on the printed circuit 214. The die 216 may be coupled on the printed circuit 214 using any suitable technique, such as, but not limited to, flip-chip bonding, wire bonding, or the like. The printed circuit 214 and the die 216 may form a circuit. The circuit as may include one or more transistors, logic gates (e.g., NAND, AND, NOR, OR, XOR, NOT, XNOR, etc.), resistors, multiplexers, registers, capacitors, inductors, diodes, wiring, and so on), and programmable hardware devices (e.g., field programmable gate arrays, programmable array logic, programmable logic devices or the like). For example, the printed circuit 214 and the die 216 may form the controller 104. The component package 202 may also include any of the controller 104, the processors 106, the memory 107, the power source 108, and/or the communication interface 110.

The component package 202 may be electrically connected to the conductive traces 112 on the bottom substrate 204. For example, the enclosure assembly 103 may include the electrical connection 218. The electrical connection 218 may connect between the conductive traces 112 and the component package 202. For instance, the electrical connection 218 may electrically connect between the conductive traces 112 and the printed circuit 214. The electrical connection 218 may include, but is not limited to, a flex circuit, wire-bonds, metal wires, ribbons, conductive epoxy, or the like.

The enclosure assembly 103 may control the heat flow between the lid 208 and the component package using the inner enclosure 212 and the porous insulation 220.

The inner enclosure 212 may enclose the component package 202. The inner enclosure 212 may conform to the component package 202. For example, the inner enclosure 212 may be machined to conform to the component package 202. The electrical connection 218 may electrically connect between the conductive traces 112 and the printed circuit 214 of the component package 202 by passing into the inner enclosure 212. The inner enclosure 212 may be disposed between the component package 202 and the porous insulation 220.

The inner enclosure 212 may be formed from a material having a high heat capacity (e.g., by volume). For example, the inner enclosure 212 may be formed from one or more metal alloys, such as, but not limited to, an iron-nickel-cobalt alloy, a nickel-iron alloy, an iron-carbon alloy, a nickel-cobalt ferrous alloy, stainless steel, a nickel-steel alloy, or the like. For instance, the inner enclosure 212 may be formed from one or more of the materials including Kovar®, Invar®, stainless steel, or another high-density metal. In embodiments, the inner enclosure 212 is Kovar. Kovar refers to a nickel-cobalt ferrous alloy designed to be compatible with the thermal expansion characteristics of borosilicate glass. The composition of KOVAR is about 29% nickel, 17% cobalt, less than 0.1% carbon, 0.2% silicon, 0.3% manganese with the balance being iron. In embodiments, the inner enclosure is Invar. Invar is a nickel-steel alloy known generically as FeNi36 (64FeNi in the U.S.). By way of another example, the inner enclosure 212 may be formed from one or more crystalline materials, such as, but not limited to, sapphire or crystalline quartz.

The porous insulation 220 may be disposed around and enclose the component package 202 and/or the inner enclosure 212. The porous insulation 220 may include one or more layers which are disposed around and enclose the component package 202 and/or the inner enclosure 212. For example, the porous insulation 220 may include a top insulation layer 220a, a side insulation layer 220b, and/or a bottom insulation layer 220c. The component package 202 and/or the inner enclosure 212 may be disposed between the top insulation layer 220a, the side insulation layer 220b, and/or the bottom insulation layer 220c. The top insulation layer 220a, the side insulation layer 220b, and/or the bottom insulation layer 220c may be disposed above, to the sides of, and below, respectively, of the component package 202 and/or the inner enclosure 212.

The top insulation layer 220a and the bottom insulation layer 220c may be shaped as a plate to cover the top and bottom of the component package 202 and/or the inner enclosure 212. For example, the top insulation layer 220a and the bottom insulation layer 220c may be shaped as a round plate, a rectangular plate (e.g., a square plate), or the like. The side insulation layer 220b may be shaped as a tube to surround sides of the component package 202 and/or the inner enclosure 212. For example, the side insulation layer 220b may be shaped as a circular tube, a rectangular tube (e.g., a square tube), or the like. The shape of the top insulation layer 220a, the side insulation layer 220b, and the bottom insulation layer 220c may be based on the shape of the component package 202 and/or the inner enclosure 212. For example, the inner enclosure 212 may be a cylinder. In embodiments, the top insulation layer 220a and the bottom insulation layer 220c are shaped as the round plate, the side insulation layer 220b is shaped as the circular tube, and the inner enclosure 212 is shaped as the cylinder.

The porous insulation 220 may be formed of a microporous material. The microporous material may include, but is not limited to, an aerogel material (e.g., silica aerogel material), a microporous ceramic material, or the like. The aerogel material and/or the microporous ceramic material may have a porosity of between 50 and 99.8%. The aerogel may include a composition of fumed silica (i.e., pyrogenic silica). The ceramic material may include a composition of alumina. During the sintering of the ceramic material, the porosity of the ceramic material may be controlled using pore formers to form the microporous ceramic material. For instance, the porosity of the ceramic material may be fabricated to have a porosity range between 95-99%. In embodiments, the microporous material is Microtherm®. Microtherm is a microporous alumina ceramic with a thermal conductivity of 0.023 W/(m·K) at 200 °C, 0.026 (W/m·K) at 400 °C, 0.031 W/(m·K) at 600 °C, and 0.039 W/(m·K) at 800 °C.

The porous insulation 220 may thermally insulate the inner enclosure 212. The porous insulation 220 may have a low thermal conductivity. For example, the thermal conductivity of the porous insulation 220 may be less than the thermal conductivity of air. Thus, the porous insulation 220 may thermally insulate the component package 202 from high process temperatures that the process condition measurement device 100 may be used to measure. The porous insulation 220 may reduce the heat transfer between the substrate assembly 102 and the component package 202. For example, the porous insulation 220 may reduce the heat transfer from the substrate assembly 102 to the component package 202. The porous insulation 220 may protect the component package 202 from excessive cold and/or heat by retarding the flow of heat thereby extending the time in which the component package 202 takes to reach the cold and/or hot temperatures. The porous insulation 220 may be beneficial to extend the range of operating conditions for the process condition measurement device 100.

The layers of the porous insulation 220 may be film layers. The top insulation layer 220a, the side insulation layer 220b, and/or the bottom insulation layer 220c may be film layers. For example, the top insulation layer 220a, the side insulation layer 220b, and/or the bottom insulation layer 220c may include a wall thickness of between 0.5 mm and 5 mm. For instance, the wall thicknesses may be between 0.5 mm and 1 mm, between 1 mm and 5 mm, or the like.

The film-based encapsulation 222 may encapsulate the porous insulation 220. The porous insulation 220 may be encapsulated between layers of the film-based encapsulation 222. The film-based encapsulation 222 may hermetically or near-hermetically seal the porous insulation 220. The hermetic seal may prevent fluid from flowing to or from the porous insulation 220. The near-hermetic seal may prevent substantially all the fluid from flowing to or from the porous insulation 220. Encapsulating the porous insulation 220 by the film-based encapsulation 222 may allow using the porous insulation 220 in applications where the porous insulation 220 is subject to contamination and/or vacuum. The microporous nature of the porous insulation 220 makes working with the porous insulation 220 difficult. For example, the porous insulation 220 may adsorb gas from the atmosphere onto the surface of the porous insulation 220. The absorption raises problems with the porous insulation 220. Also, the porous insulation 220 may absorb liquid adhesives within the structure of the porous insulation 220 before the adhesive 210 is cured. Encapsulating the porous insulation 220 may prevent the gas and the liquid adhesive from infiltrating into and degrading the porous insulation 220. Encapsulating the porous insulation 220 may also prevent gas species from outgassing from the porous insulation 220 to outside of the process condition measurement device 100 when subject to high temperatures.

The film-based encapsulation 222 may be a film. For example, the film-based encapsulation 222 may include a wall thickness of between 0.005 mm and 0.25 mm (i.e., between 5 and 250 micrometers). The film-based encapsulation 222 may be formed of any film material which may hermetically or near-hermetically seal the porous insulation 220, such as, but not limited to, a polymer film, a metal-foil film, a metal-coated polymer film, the like, or a combination of materials. For the construction of the process condition measurement device 100, it is advantageous to construct the process condition measurement device 100 as thin as possible while maintaining the hermetic or near-hermetic seal. The polymer film may provide the near-hermetic seal. The metal-foil film and/or the metal-coated polymer film may provide the hermetic seal. The polymer film may be advantageous to provide additional thermal insulation, as compared to the metal-foil film. However, the metal-foil film may be more impervious to gas flow and provide a tighter seal. In embodiments, the film-based encapsulation 222 may be a metal-coated polymer film. For example, the metal-coated polymer film may be a polyester film (e.g., mylar®) coated on one or both sides by a metal-foil film. The electrical connection 218 may be electrically-insulated from the film-based encapsulation 222 to prevent shorting with the film-based encapsulation 222.

The film-based encapsulation 222 may have a much higher thermal conductivity than the porous insulation 220. For example, the thermal conductivity of the film-based encapsulation 222 may be at least one order of magnitude larger than the porous insulation 220.

The porous insulation 220 may be under vacuum pressure. The vacuum pressure may refer to any pressure that is lower than atmospheric pressure. The film-based encapsulation 222 may maintain the porous insulation 220 at the vacuum pressure by the hermetic or near-hermetic seal. The porous insulation 220 may be under the vacuum pressure to reduce the thermal conductivity of the porous insulation 220. The porous insulation 220 may be full of micro-sized pores. The porous insulation 220 may adsorb species of gas (e.g., air) and/or absorb species of liquid before being evacuated. Under vacuum pressure the species of gas may outgas from the porous insulation 220. The porous insulation 220 may then be encapsulated by the film-based encapsulation 222 to maintain the vacuum pressure. The porous insulation 220 being under vacuum pressure may also prevent the porous insulation 220 and the film-based encapsulation 222 from swelling when the process condition measurement device 100 is used in a process chamber subject to vacuum.

The joint 224 may join the film-based encapsulation 222 around the porous insulation 220. The joint 224 may include any suitable joint, such as, but not limited to, an adhesive joint, a weld joint, or the like. The adhesive joint may be heat-activated. The porous insulation 220, the film-based encapsulation 222, and the joint 224 may form a pouch assembly, an envelope, a membrane, or the like. The joint 224 may form a hermetic or near-hermetic seal with the film-based encapsulation 222 for the porous insulation 220. The porous insulation 220 may be placed under the vacuum pressure before the joint 224 joins the film-based encapsulation 222 around the porous insulation 220. The film-based encapsulation 222 may be formed of one or more upper and lower film-halves. The joint 224 may join the upper and lower film-halves. For example, the joint 224 may join the upper and lower film-halves via a lamination process, or the like. The porous insulation 220 may or may not plastically deform during the lamination process. It is desirable that the porous insulation 220 does not plastically deform to maintain a lower thermal conductivity. A portion of the material of the joint 224 (e.g., adhesive joint, weld joint) may be absorbed within a portion of the porous insulation 220, without significantly impacting the thermal conductivity of the porous insulation 220.

Referring to FIGS. 2A-2C, the film-based encapsulation 222 may include a top film-based encapsulation 222a, a side film-based encapsulation 222b, and a bottom film-based encapsulation 222c, in accordance with one or more embodiments of the present disclosure. The top film-based encapsulation 222a, the side film-based encapsulation 222b, and the bottom film-based encapsulation 222c may be separate components.

The top film-based encapsulation 222a, the side film-based encapsulation 222b, and the bottom film-based encapsulation 222c may encapsulate the top insulation layer 220a, the side insulation layer 220b, and the bottom insulation layer 220c, respectively. The shape of the top film-based encapsulation 222a, the side film-based encapsulation 222b, and the bottom film-based encapsulation 222c may encapsulate the top insulation layer 220a, the side insulation layer 220b, and the bottom insulation layer 220c by conforming to said layers. The top film-based encapsulation 222a may not encapsulate the side insulation layer 220b and the bottom insulation layer 220c, the side film-based encapsulation 222b may not encapsulate the top insulation layer 220a and the bottom insulation layer 220c, and/or the bottom film-based encapsulation 222c may not encapsulate the top insulation layer 220a and the side insulation layer 220b. In embodiments, the top insulation layer 220a and the bottom insulation layer 220c are shaped as the round plate with the top film-based encapsulation 222a and the bottom film-based encapsulation 222c conforming to the round plate shape and the side insulation layer 220b is shaped as the circular tube with the side film-based encapsulation 222b conforming to the circular tube shape. For example, the top film-based encapsulation 222a and the bottom film-based encapsulation 222c may be plate-shaped encapsulations and the side film-based encapsulation 222b may be a circular-tube shaped encapsulation.

The top film-based encapsulation 222a and/or the bottom film-based encapsulation 222c may overhang the inner enclosure 212. For example, the top film-based encapsulation 222a and/or the bottom film-based encapsulation 222c may be wider than the inner enclosure 212. The side film-based encapsulation 222b may be disposed between and abut the top film-based encapsulation 222a and/or the bottom film-based encapsulation 222c.

The component package 202 and/or the inner enclosure 212 may not be enclosed in any of the top film-based encapsulation 222a, the side film-based encapsulation 222b, and the bottom film-based encapsulation 222c. The top film-based encapsulation 222a, the side film-based encapsulation 222b, and the bottom film-based encapsulation 222c may be disposed between the component package 202 and/or the inner enclosure 212 and respective of the top insulation layer 220a, the side insulation layer 220b, and the bottom insulation layer 220c. For example, the top film-based encapsulation 222a, the side film-based encapsulation 222b, and the bottom film-based encapsulation 222c may abut between the inner enclosure 212 and respective of the top insulation layer 220a, the side insulation layer 220b, and the bottom insulation layer 220c. The inner enclosure 212 may provide a mechanical surface to flatten out and abut with the top film-based encapsulation 222a, the side film-based encapsulation 222b, and the bottom film-based encapsulation 222c. The bottom film-based encapsulation 222c may mechanically support the component package 202 and/or the inner enclosure 212.

The top film-based encapsulation 222a, the side film-based encapsulation 222b, and the bottom film-based encapsulation 222c may or may not be adhered to the inner enclosure 212 and/or to each other. For example, the adhesive 210 may be between the lid 208 and the top film-based encapsulation 222a, the side film-based encapsulation 222b, and/or the bottom film-based encapsulation 222c. The adhesive 210 may or may not flow between the inner enclosure 212, the top film-based encapsulation 222a, the side film-based encapsulation 222b, and/or the bottom film-based encapsulation 222c.

Each of the top insulation layer 220a, the side insulation layer 220b, and the bottom insulation layer 220c may be under the vacuum pressure. The top insulation layer 220a, the side insulation layer 220b, and the bottom insulation layer 220c may or may not include the same vacuum pressure. For example, the top film-based encapsulation 222a, the side film-based encapsulation 222b, and the bottom film-based encapsulation 222c may hermetically or near-hermetically seal respective of the top insulation layer 220a, the side insulation layer 220b, and the bottom insulation layer 220c at the same or different vacuum pressures.

The joint 224 may include a top joint 224a, a side joint 224b, and a bottom joint 224c. The top joint 224a may join the top film-based encapsulation 222a around the top insulation layer 220a, the side joint 224b may join the side film-based encapsulation 222b around the side insulation layer 220b, and/or the bottom joint 224c may join the bottom film-based encapsulation 222c around the bottom insulation layer 220c. The top insulation layer 220a, the side insulation layer 220b, and the bottom insulation layer 220c may be placed under the vacuum pressure before the top joint 224a, the side joint 224b, and the bottom joint 224c joins respective of the top film-based encapsulation 222a, the side film-based encapsulation 222b, and the bottom film-based encapsulation 222c around respective of the top insulation layer 220a, the side insulation layer 220b, and the bottom insulation layer. Each of the top film-based encapsulation 222a, the side film-based encapsulation 222b, and the bottom film-based encapsulation 222c may be formed of upper and lower film-halves. The top joint 224a, the side joint 224b, and the bottom joint 224c may join the upper and lower film-halves of respective of the top film-based encapsulation 222a, the side film-based encapsulation 222b, and the bottom film-based encapsulation 222c.

A portion of the electrical connection 218 may be disposed between the top film-based encapsulation 222a and the bottom film-based encapsulation 222c. For example, a portion of the electrical connection 218 may be disposed between the top film-based encapsulation 222a and the side film-based encapsulation 222b or may be disposed between the side film-based encapsulation 222b and the bottom film-based encapsulation 222c. As depicted, the portion of the electrical connection 218 is disposed between the side film-based encapsulation 222b and the bottom film-based encapsulation 222c, although this is not intended to be limiting.

Referring to FIG. 3, the film-based encapsulation 222 may include a multi-layer film-based encapsulation 222d, in accordance with one or more embodiments of the present disclosure. The multi-layer film-based encapsulation 222d may comprise of one or more layers of electrically conductive and non-conductive materials.

The multi-layer film-based encapsulation 222d may encapsulate component package 202, the inner enclosure 212, the top insulation layer 220a, the side insulation layer 220b, and/or the bottom insulation layer 220c.

The multi-layer film-based encapsulation 222d may be considered a multi-layer encapsulation by encapsulating multiple layers of the porous insulation 220. The multi-layer film-based encapsulation 222d may encapsulate the top insulation layer 220a, the side insulation layer 220b, and the bottom insulation layer 220c. The shape of the multi-layer film-based encapsulation 222d may encapsulate the top insulation layer 220a, the side insulation layer 220b, and the bottom insulation layer 220c by conforming to said layers. In embodiments, the top insulation layer 220a and the bottom insulation layer 220c are shaped as the round plate, the side insulation layer 220b is shaped as the circular tube, and the multi-layer film-based encapsulation 222d is shaped as a hollow-cylinder to conform to the top insulation layer 220a, the side insulation layer 220b, and the bottom insulation layer 220c.

The component package 202 and/or the inner enclosure 212 may be encapsulated in the multi-layer film-based encapsulation 222d with the top insulation layer 220a, the side insulation layer 220b, and the bottom insulation layer 220c. In this regard, the porous insulation 220, the component package 202, and/or the inner enclosure 212 may be encapsulated together. The top insulation layer 220a, the side insulation layer 220b, and the bottom insulation layer 220c may abut the top, sides, and bottom, respectively, of the inner enclosure 212. The bottom insulation layer 220c may mechanically support the component package 202 and/or the inner enclosure 212.

The top insulation layer 220a and/or the bottom insulation layer 220c may overhang the inner enclosure 212. For example, the top insulation layer 220a and/or the bottom insulation layer 220c may be wider than the inner enclosure 212. The side insulation layer 220b may be disposed between and abut the top insulation layer 220a and/or the bottom insulation layer 220c.

The joint 224 may be a joint 224d. The joint 224d may join the multi-layer film-based encapsulation 222d around the top insulation layer 220a, the side insulation layer 220b, and/or the bottom insulation layer 220c. The top insulation layer 220a, the side insulation layer 220b, and the bottom insulation layer 220c may be placed under the vacuum pressure before the joint 224d joins the multi-layer film-based encapsulation 222d around the top insulation layer 220a, the side insulation layer 220b, and/or the bottom insulation layer 220c. The multi-layer film-based encapsulation 222d may be formed of an upper and lower film-half. The joint 224d may join the upper and lower film-half of the multi-layer film-based encapsulation 222d.

The electrical connection 218 may electrically connect between the conductive traces 112 and the component package 202 by passing into the multi-layer film-based encapsulation 222d. For example, the electrical connection 218 may pass into the multi-layer film-based encapsulation 222d by passing through the joint 224d. By way of another example, the electrical connection 218 may pass into the multi-layer film-based encapsulation 222d by passing through an electrical feedthrough 302 defined by the multi-layer film-based encapsulation 222d. The electrical feedthrough 302 may pass through the multi-layer film-based encapsulation 222d. For example, the electrical feedthrough 302 may pass through a top (as depicted), a side, and/or a bottom of the multi-layer film-based encapsulation 222d. Encapsulating the component package 202 and/or the inner enclosure 212 in the multi-layer film-based encapsulation 222d may necessitate passing the electrical connection 218 into the multi-layer film-based encapsulation 222d. The joint 224d and/or the electrical feedthrough 302 may maintain the hermetic or near-hermetic seal. The joint 224d and/or the electrical feedthrough 302 may be electrically insulated from the multi-layer film-based encapsulation 222d to prevent shorting the electrical connection 218 to the multi-layer film-based encapsulation 222d. For example, the joint 224d and/or the electrical feedthrough 302 may include a metal via in a ceramic matrix that receives the electrical connection 218. The electrical feedthrough 302 may be brazed to the multi-layer film-based encapsulation 222d to maintain the hermetic seal.

The enclosure assembly 103 with the multi-layer film-based encapsulation 222d may include some advantages and disadvantages compared to the enclosure assembly 103 with the top film-based encapsulation 222a, the side film-based encapsulation 222b, and the bottom film-based encapsulation 222c. The enclosure assembly 103 with the multi-layer film-based encapsulation 222d may have a reduced height than the enclosure assembly 103 with the top film-based encapsulation 222a, the side film-based encapsulation 222b, and the bottom film-based encapsulation 222c, because the top film-based encapsulation 222a and the bottom film-based encapsulation 222c may require two additional layers of film than the multi-layer film-based encapsulation 222d. However, the enclosure assembly 103 with the multi-layer film-based encapsulation 222d may have the electrical connection 218 pass into the multi-layer film-based encapsulation 222d, which may raise the risk of hermetic or near-hermetic seal failure.

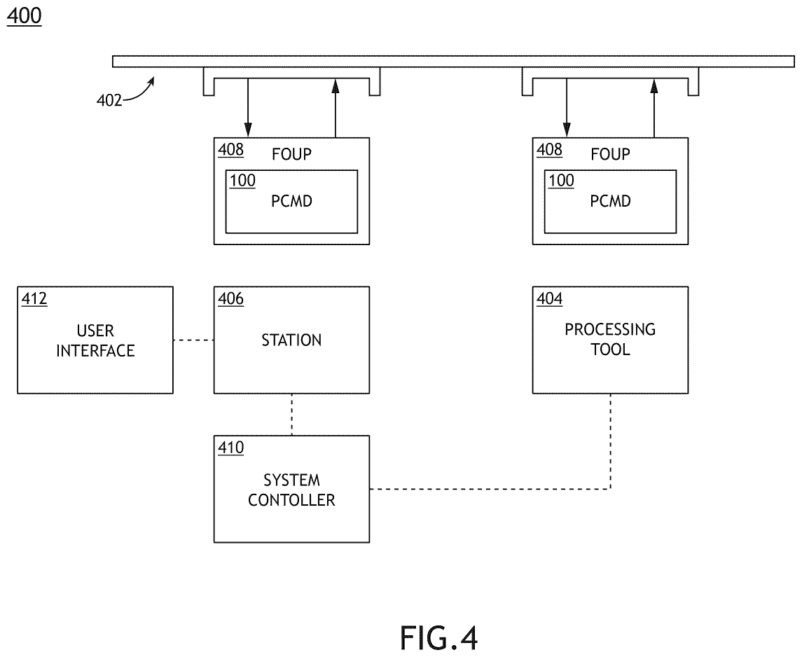

FIG. 4 depicts a simplified block diagram of a system 400, in accordance with one or more embodiments of the present disclosure. The system 400 may be a substrate processing system. The system 400 may include the process condition measurement device 100, an automatic material handling system 402 (AMHS), a processing tool 404, a station 406, front opening unified pods 408 (FOUP), a system controller 410, and/or a user interface 412.

The front opening unified pods 408 may be automation ready FOUPs that can communicate to a device manufacturer's fab automation system. The front opening unified pods 408 may include one or more of the process condition measurement devices 100. The front opening unified pods 408 may be configured to receive and secure the process condition measurement devices 100. The process condition measurement device 100 may be housed within the front opening unified pods 408. The front opening unified pods 408 may include a substrate carrier which may be integrated with the system 400. The front opening unified pods 408 may provide an environment for storing and transporting the process condition measurement device 100.

The front opening unified pods 408 may be configured to provide power to the power source 108. For example, the front opening unified pods 408 may recharge the power source 108.

The front opening unified pods 408 may be configured to exchange data with the communication interface 110. For example, the front opening unified pods 408 may be configured to receive the sensor measurements 115 from the communication interface 110. The controller 104 of the process condition measurement device 100 may be communicatively coupled to the front opening unified pods 408 by wireless communication. For instance, the front opening unified pods 408 may include communication circuitry (not depicted). The communication circuitry may include, but is not limited to, one or more communication antennas (e.g., communication coil). The communication circuitry may be configured to establish a communication link between the controller 104 and the front opening unified pods 408. The front opening unified pods 408 may include a FOUP interface (not depicted). The FOUP interface may be the interface by which the front opening unified pods 408 may be configured to receive recipes, mission start command, relays back mission data, and the like.

The automatic material handling system 402 may position the front opening unified pods 408 in three-dimensions. The automatic material handling system 402 may include an Overhead track (OHT) system. The space occupied by the automatic material handling system 402 may be above the normal floor working level. The automatic material handling system 402 may pick the front opening unified pods 408 from the station 406 and transport the front opening unified pods 408 to the processing tool 404. Similarly, the automatic material handling system 402 may pick the front opening unified pods 408 from the processing tool 404 and transport the front opening unified pods 408 to the station 406.

The station 406 may be an automation station. The station 406 may be an Automated material handling system (AMHS) compatible station. The station 406 may host the front opening unified pods 408. The station 406 may be configured to receive the front opening unified pods 408. The station 406 may communicate with the front opening unified pods 408. The station 406 may also recharge the front opening unified pods 408. The station 406 may communicate with the system controller 410.

The processing tool 404 may be configured to receive the process condition measurement device 100. The automatic material handling system 402 may also be configured to remove the process condition measurement device 100 from the front opening unified pods 408 and place the process condition measurement device 100 within a pathway of the illumination.

The process condition measurement device 100 may include a thickness which is sufficiently small to meet a specification of a processing chamber (e.g., epitaxy chamber, plasma etch chamber) of the processing tool 404. For example, the process condition measurement device 100 may include a maximum thickness of 10 mm or less to fit into various process chambers. For instance, the maximum thickness may be 50 mm or less, 10 mm or less, 6 mm or less, 5 mm or less, 2 mm or less, or smaller.

The processing tool 404 may be configured to generate illumination. The processing tool 404 may be configured to generate the illumination using a plasma or the like. For example, the processing tool 404 may include an EUV lithography tool or the like. The processing tool 404 may generate the illumination in an image plane on the process condition measurement device 100.

The process condition measurement device 100 may be configured to monitor process conditions within a process chamber of the processing tool 404. The process condition measurement device 100 may provide a metrology platform for calibrating and monitoring the illumination in the processing tool 404. The processing tool 404 may use the sensor measurements 115 for optimal semiconductor process performance.

The process condition measurement device 100 may be subject to extreme conditions within the processing tool 404. The extreme conditions may include including aggressive chemistry, high and low temperature extremes. The extreme conditions may be found in etch environments or other wafer processing environments. The material of the substrate assembly 102 and the lid 208 may cause negligible contamination in the processing tool 404. The bottom substrate 204, the top substrate 206, and/or the lid 208 may shield the enclosure assembly 103 from extreme conditions (e.g., high RF, high heat flux, high electromagnetic radiation) within process chambers of the processing tool 404. The lid 208 may protect the enclosure assembly 103 from the extreme conditions. For example, the lid 208 may prevent the enclosure assembly 103 from being chemically etched during a plasma etch process. Thus, the process condition measurement device 100 may include the enclosure assembly 103 which may survive the extreme environments.

The process condition measurement device 100 may be configured to autonomously perform a measurement of the illumination in response to a factory automation request.

The system controller 410 and the process condition measurement device 100 may include an interface through the front opening unified pods 408 and the station 406 and/or an interface through the processing tool 404. The system controller 410 may process data from the process condition measurement device 100 for statistical processing control (SPC). The system 400 may have the ability to automatically add data collected from the process condition measurement device 100 to a database within the system controller 410.

A mission may be a data collection session of the process condition measurement device 100 and the following download of data from the process condition measurement device 100. The mission may be initiated by the system controller 410 for the purpose to ascertain the health of the processing tool 404. The mission may be communicated to the station 406 that hosts the front opening unified pods 408. The station 406 may communicate the mission to the front opening unified pods 408. The front opening unified pods 408 may then communicate the mission to the process condition measurement device 100. The process condition measurement device 100 may then execute the mission for determining the health of the processing tool 404.

The user interface 412 may be communicatively coupled to the station 406. The user interface 412 may include, but is not limited to, one or more desktops, laptops, tablets, and the like. The user interface 412 may include a display used to display data of the system to a user. The display of the user interface 412 may include any display known in the art. For example, the display may include, but is not limited to, a liquid crystal display (LCD), an organic light-emitting diode (OLED) based display, or a CRT display. Those skilled in the art should recognize that any display device capable of integration with a user interface is suitable for implementation in the present disclosure. A user may input selections and/or instructions responsive to data displayed to the user via a user input device of the user interface 412.

Any of the various components of the system 400 may be configured to communicate using a selected communications protocol. For example, the selected communications protocol may include an industry standard communications protocol consistent with standards defined by the Semiconductor Equipment and Materials Institute (SEMI). These standards are referred to as SEMI Equipment Communications Standards (SECS) and Generic Equipment Model (GEM).

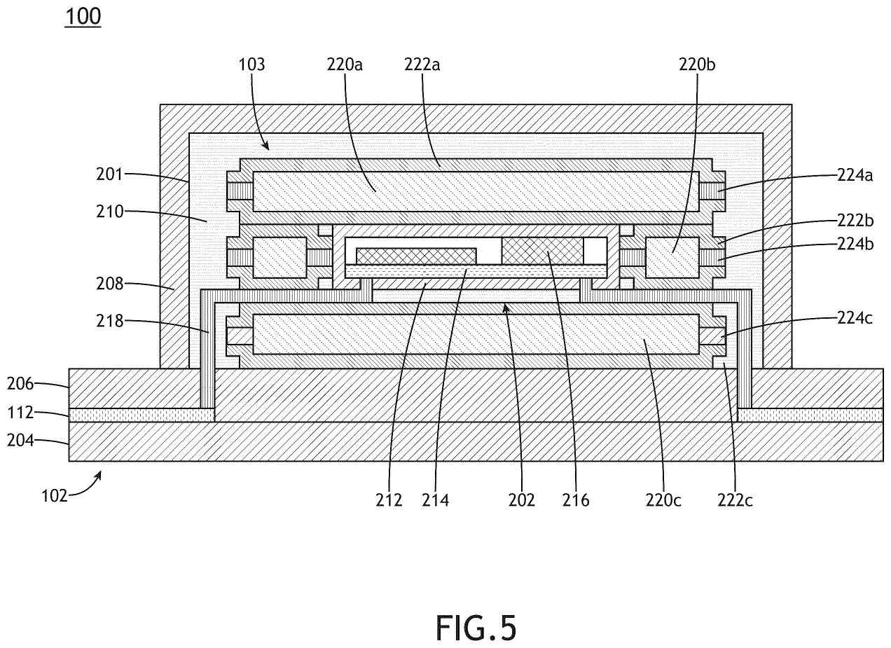

FIG. 5 depicts the process condition measurement device 100, in accordance with one or more embodiments of the present disclosure. Although the top substrate 206 is described as defining the cavity 201 with the lid 208, this is not intended as a limitation of the present disclosure. The lid 208 may define the cavity 201 by itself. The enclosure assembly 103 may be supported on the top surface of the top substrate 206. The electrical connection 218 may extend through the top substrate 206 to the conductive traces 112. The enclosure assembly 103 which is supported on the surface of the top substrate 206 may include the top film-based encapsulation 222a, the side film-based encapsulation 222b, and the bottom film-based encapsulation 222c (as depicted) and/or may include the multi-layer film-based encapsulation 222d (not depicted). Supporting the enclosure assembly 103 on the surface of the top substrate 206 may be disadvantageous due to height considerations. For example, the top substrate 206 defining the cavity 201 with the lid 208 may be beneficial to reduce the height of the enclosure assembly 103 by the thickness of the top substrate 206.

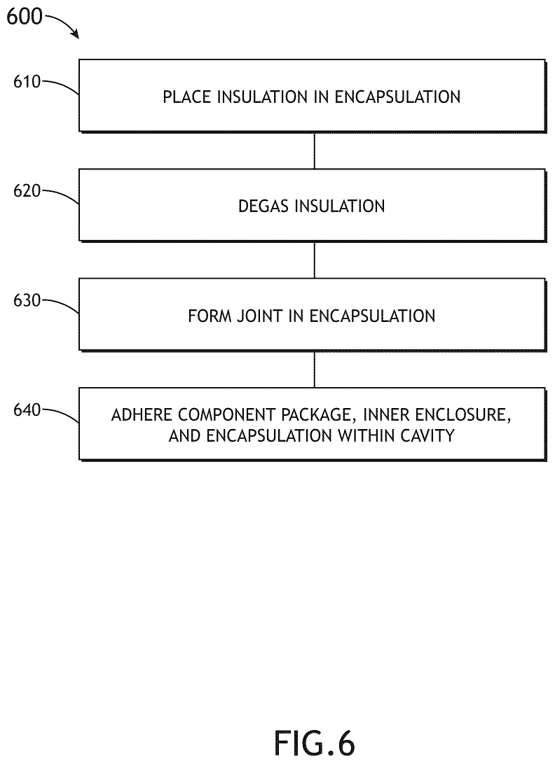

FIG. 6 depicts a flow diagram of a method 600, in accordance with one or more embodiments of the present disclosure. The method 600 may be a method of manufacturing the enclosure assembly 103 with the top film-based encapsulation 222a, the side film-based encapsulation 222b, and the bottom film-based encapsulation 222c. The embodiments and enabling technologies described previously herein in the context of the process condition measurement device 100 should be interpreted to extend to the method 600. It is further noted, however, that the method is not limited to the architecture of process condition measurement device 100.

In a step 610, a top insulation layer, a side insulation layer, and a bottom insulation layer may be placed within a top film-based encapsulation, a side film-based encapsulation, and a bottom film-based encapsulation, respectively. For example, the top insulation layer 220a, the side insulation layer 220b, and the bottom insulation layer 220c may be placed within the top film-based encapsulation 222a, the side film-based encapsulation 222b, and the bottom film-based encapsulation 222c, respectively.

In a step 620, the top insulation layer, the side insulation layer, and the bottom insulation layer may be degassed. For example, the top insulation layer 220a, the side insulation layer 220b, and the bottom insulation layer 220c may be degassed. The top insulation layer 220a, the side insulation layer 220b, and the bottom insulation layer 220c may be degassed by evacuation and/or heating.

In a step 630, a top joint, a side joint, and a bottom joint may be formed to encapsulate the top insulation layer, the side insulation layer, and the bottom insulation layer within respective of the top film-based encapsulation, the side film-based encapsulation, and the bottom film-based encapsulation. For example, the top joint 224a, the side joint 224b, and the bottom joint 224c may be formed to encapsulate the top insulation layer 220a, the side insulation layer 220b, and the bottom insulation layer 220c within respective of the top film-based encapsulation 222a, the side film-based encapsulation 222b, and the bottom film-based encapsulation 222c. The top joint 224a, the side joint 224b, and the bottom joint 224c may be formed by welding, adhesive, or the like.

In a step 640, a component package, an inner enclosure, the top film-based encapsulation, the side film-based encapsulation, and the bottom film-based encapsulation may be adhered within a cavity by an adhesive. For example, the component package 202, the inner enclosure 212, the top film-based encapsulation 222a, the side film-based encapsulation 222b, and the bottom film-based encapsulation 222c may be adhered within the cavity 201 by the adhesive 210. The top film-based encapsulation 222a, the side film-based encapsulation 222b, and the bottom film-based encapsulation 222c may prevent the liquid adhesive from contaminating the top insulation layer 220a, the side insulation layer 220b, and the bottom insulation layer 220c before the adhesive 210 is cured.

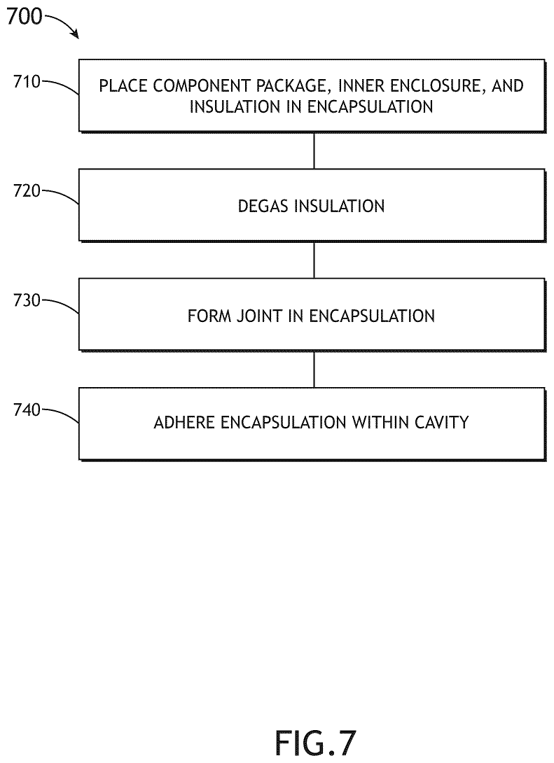

FIG. 7 depicts a flow diagram of a method 700, in accordance with one or more embodiments of the present disclosure. The method 700 may be a method of manufacturing the enclosure assembly 103 with the multi-layer film-based encapsulation 222d. The embodiments and enabling technologies described previously herein in the context of the process condition measurement device 100 should be interpreted to extend to the method 700. It is further noted, however, that the method is not limited to the architecture of process condition measurement device 100.

In a step 710, a component package, an inner enclosure, a top insulation layer, a side insulation layer, and a bottom insulation layer may be placed within a multi-layer film-based encapsulation 222d. For example, the component package 202, the inner enclosure 212, the top insulation layer 220a, the side insulation layer 220b, and the bottom insulation layer 220c may be placed within the multi-layer film-based encapsulation 222d.

In a step 720, the top insulation layer, the side insulation layer, and the bottom insulation layer may be degassed. For example, the top insulation layer 220a, the side insulation layer 220b, and the bottom insulation layer 220c may be degassed. The top insulation layer 220a, the side insulation layer 220b, and the bottom insulation layer 220c may be degassed by evacuation and/or heating.

In a step 730, a joint may be formed to encapsulate the component package, the inner enclosure, the top insulation layer, the side insulation layer, and the bottom insulation layer within the multi-layer film-based encapsulation. For example, the joint 224d may be formed to encapsulate the component package 202, the inner enclosure 212, the top insulation layer 220a, the side insulation layer 220b, and the bottom insulation layer 220c within the multi-layer film-based encapsulation 222d. The joint 224d may be formed by welding, adhesive, or the like.

In a step 740, the multi-layer film-based encapsulation may be adhered within a cavity by an adhesive. For example, the multi-layer film-based encapsulation 222d may be adhered within the cavity 201 by the adhesive 210. The multi-layer film-based encapsulation 222d may prevent the liquid adhesive from contaminating the top insulation layer 220a, the side insulation layer 220b, and the bottom insulation layer 220c before the adhesive 210 is cured.

Referring generally again to the figures. Although the enclosure assembly 103 is described and depicted with the side insulation layer 220b, this is not intended to be limiting. For example, the shape of the component package 202 and/or the inner enclosure 212 may or may not permit manufacturing the shape of the side insulation layer 220b. However, the addition of the side insulation layer 220b may be beneficial to reduce the lateral heat flow.

As used herein, the term “thermally insulating” refers to the property of being resistant to transfer of heat across a material or medium because of low thermal conductivity and/or high heat capacity. As used herein, the term “thermally absorbing” refers to the property of being resistant to transfer of heat because of high heat capacity, but not necessarily due to low thermal conductivity. As may be seen from the foregoing, “thermally absorbing” is a subset of “thermally insulating.” As used herein, the term “heat capacity” refers to the volumetric heat capacity of the material; it is the amount of heat required to change an object's temperature by a given amount. An object with a higher heat capacity requires a greater amount of heat to raise its temperature the same amount as an object of identical volume with a lower heat capacity. An encapsulation may be an enclosure which include one or more layers formed on the body and in intimate contact therewith.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

In embodiments, a controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

The memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive, and the like. The memory medium may include flash memory cells, or other type memory, discrete EPROM or EEPROM, or the like. It is further noted that memory medium may be housed in a common controller housing with the one or more processors. In one embodiment, the memory medium may be located remotely with respect to the physical location of the one or more processors and controller. For instance, the one or more processors of controller may access a remote memory (e.g., server), accessible through a network (e.g., internet, intranet, and the like).

As used throughout the present disclosure, the term “substrate” generally refers to a substrate formed of a semiconductor or non-semiconductor material (e.g., thin filmed glass, or the like). For example, a semiconductor or non-semiconductor material may include, but is not limited to, monocrystalline silicon, gallium arsenide, indium phosphide, or a glass material. A substrate may include one or more layers. For example, such layers may include, but are not limited to, a resist (including a photoresist), a dielectric material, a conductive material, and a semiconductive material. Many different types of such layers are known in the art, and the term sample as used herein is intended to encompass a substrate on which all types of such layers may be formed. One or more layers formed on a substrate may be patterned or un-patterned. For example, a substrate may include a plurality of dies, each having repeatable patterned features. Formation and processing of such layers of material may ultimately result in completed devices. Many different types of devices may be formed on a substrate, and the term substrate as used herein is intended to encompass a substrate on which any type of device known in the art is being fabricated. Further, for the purposes of the present disclosure, the term substrate and wafer should be interpreted as interchangeable. In addition, for the purposes of the present disclosure, the terms patterning device, mask, and reticle should be interpreted as interchangeable.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all its material advantages. The form described is merely explanatory, and it is the intention of the following claims to encompass and include such changes. Furthermore, it is to be understood that the invention is defined by the appended claims.

What is claimed:

1. A process condition measurement device comprising:
a substrate assembly comprising a bottom substrate and a top substrate;
a conductive trace, wherein the conductive trace is formed on or embedded in the bottom substrate, wherein the top substrate is disposed over and covers the conductive trace;
a lid defining a cavity;
an adhesive; and
an enclosure assembly, wherein the lid is disposed above and covers the enclosure assembly and the adhesive, wherein the enclosure assembly is adhered within the cavity by the adhesive, wherein the enclosure assembly comprises:
a component package,
an inner enclosure, wherein the inner enclosure encloses the component package;
an electrical connection, wherein the electrical connection connects between the conductive trace and the component package by passing into the inner enclosure;
a porous insulation, wherein the porous insulation comprises at least a top insulation layer and a bottom insulation layer, wherein the inner enclosure is disposed between the top insulation layer and the bottom insulation layer,
a film-based encapsulation, wherein the film-based encapsulation encapsulates the porous insulation, and
a joint, wherein the joint joins the film-based encapsulation around the porous insulation.

2. The process condition measurement device of claim 1, wherein at least one of the bottom substrate, the top substrate, or the lid comprise at least one of silicon, glass, aluminum oxide, silicon carbide, or quartz, wherein the electrical connection comprises at least one of a flex circuit, a wire-bond, a metal wire, a ribbon, or a conductive epoxy, wherein the inner enclosure comprises at least one of an iron-nickel-cobalt alloy, a nickel-iron alloy, an iron-carbon alloy, a nickel-cobalt ferrous alloy, stainless steel, or a nickel-steel alloy.

3. The process condition measurement device of claim 1, wherein the lid is disposed above and partially covers the top substrate, wherein the lid and the top substrate are directly bonded.

4. The process condition measurement device of claim 1, comprising a controller, a power source, and a communication interface, wherein the component package comprises at least one of the controller, the power source, the communication interface, or a high-heat capacity thermal mass.

5. The process condition measurement device of claim 1, wherein the cavity conforms to the enclosure assembly, wherein at least one of:
the top substrate and the lid define the cavity, wherein the enclosure assembly is supported by a surface of the bottom substrate; or
the top substrate does not define the cavity, wherein the enclosure assembly is supported on a surface of the top substrate.

6. The process condition measurement device of claim 1, wherein the porous insulation comprises a side insulation layer, wherein the inner enclosure is disposed between the side insulation layer, wherein the porous insulation is disposed around and encloses the inner enclosure.

7. The process condition measurement device of claim 6, wherein the top insulation layer and the bottom insulation layer are shaped as one of a round plate or a rectangular plate, wherein the side insulation layer is shaped as one of a circular tube or a rectangular tube.

8. The process condition measurement device of claim 1, wherein the porous insulation is formed of a microporous material, wherein the microporous material comprises at least one of an aerogel material or a microporous ceramic material.

9. The process condition measurement device of claim 1, wherein the top insulation layer and the bottom insulation layer are films.

10. The process condition measurement device of claim 9, wherein the top insulation layer and the bottom insulation layer have a wall thickness of between 0.5 mm and 5 mm.

11. The process condition measurement device of claim 1, wherein the film-based encapsulation is formed of at least one of a polymer film, a metal-foil film, or a metal-coated polymer film.

12. The process condition measurement device of claim 11, wherein the film-based encapsulation is formed of the metal-coated polymer film, wherein the metal-coated polymer film comprises a polyester film coated on one or both sides by a metal-foil film.

13. The process condition measurement device of claim 1, wherein the film-based encapsulation comprises a wall thickness of between 0.005 mm and 0.25 mm.

14. The process condition measurement device of claim 1, wherein the film-based encapsulation hermetically or near-hermetically seals the porous insulation, wherein the porous insulation is under vacuum pressure.

15. The process condition measurement device of claim 1, wherein the joint comprises at least one of an adhesive joint or a weld joint, wherein the adhesive joint is heat-activated.

16. The process condition measurement device of claim 1, wherein the film-based encapsulation comprises at least a top film-based encapsulation and a bottom film-based encapsulation wherein the top film-based encapsulation encapsulates the top insulation layer, wherein the bottom film-based encapsulation encapsulates the bottom insulation layer, wherein the top film-based encapsulation is disposed between the inner enclosure and the top insulation layer, wherein the bottom film-based encapsulation is disposed between the inner enclosure and the bottom insulation layer, wherein the joint comprises a top joint and a bottom joint, wherein the top joint joins the top film-based encapsulation around the top insulation layer, wherein the bottom joint joins the bottom film-based encapsulation around the bottom insulation layer.

17. The process condition measurement device of claim 16, wherein the top film-based encapsulation and the bottom film-based encapsulation each overhang the inner enclosure, wherein a portion of the electrical connection is disposed between the top film-based encapsulation and the bottom film-based encapsulation.

18. The process condition measurement device of claim 17, wherein the porous insulation comprises a side insulation layer, wherein the film-based encapsulation comprises a side film-based encapsulation, wherein the side film-based encapsulation encapsulates the side insulation layer, wherein the side film-based encapsulation is disposed between the top film-based encapsulation and the bottom film-based encapsulation, wherein the side film-based encapsulation is disposed between the inner enclosure and the side insulation layer, wherein the joint comprises a side joint, wherein the side joint joins the side film-based encapsulation around the side insulation layer, wherein the portion of the electrical connection is disposed between at least one of the top film-based encapsulation and the side film-based encapsulation or is disposed between the side film-based encapsulation and the bottom film-based encapsulation.

19. The process condition measurement device of claim 1, wherein the film-based encapsulation comprises a multi-layer film-based encapsulation, wherein the multi-layer film-based encapsulation encapsulates at least the component package, the inner enclosure, top insulation layer, and the bottom insulation layer, wherein the electrical connection connects between the conductive trace and the component package by passing into the multi-layer film-based encapsulation.

20. The process condition measurement device of claim 19, wherein the top insulation layer and the bottom insulation layer overhang the inner enclosure, wherein the porous insulation comprises a side insulation layer, wherein the multi-layer film-based encapsulation encapsulates the side insulation layer, wherein the side insulation layer is disposed between and abuts the top insulation layer and the bottom insulation layer.

21. The process condition measurement device of claim 19, wherein one of:
the electrical connection passes through the joint; or
the multi-layer film-based encapsulation comprises an electrical feedthrough, wherein the electrical connection passes through the electrical feedthrough.

22. The process condition measurement device of claim 1, wherein the process condition measurement device is configured to be received by a front opening unified pod, wherein the process condition measurement device comprises a thickness of 50 mm or less.

23. The process condition measurement device of claim 22, wherein the process condition measurement device comprises a thickness of 10 mm or less.

24. A system comprising:
a process condition measurement device comprising:
a substrate assembly comprising a bottom substrate and a top substrate;
a conductive trace, wherein the conductive trace is formed on or embedded in the bottom substrate, wherein the top substrate is disposed over and covers the conductive trace;
a lid defining a cavity;
an adhesive; and
an enclosure assembly, wherein the lid is disposed above and covers the enclosure assembly and the adhesive, wherein the enclosure assembly is adhered within the cavity by the adhesive, wherein the enclosure assembly comprises:
a component package,
an inner enclosure, wherein the inner enclosure encloses the component package;
an electrical connection, wherein the electrical connection connects between the conductive trace and the component package by passing into the inner enclosure;
a porous insulation, wherein the porous insulation comprises at least a top insulation layer and a bottom insulation layer, wherein the inner enclosure is disposed between the top insulation layer and the bottom insulation layer,
a film-based encapsulation, wherein the film-based encapsulation encapsulates the porous insulation, and
a joint, wherein the joint joins the film-based encapsulation around the porous insulation; and
a front opening unified pod, wherein the front opening unified pod is configured to receive the process condition measurement device.

25. A method comprising:
placing a top insulation layer, a side insulation layer, and a bottom insulation layer within respective of a top film-based encapsulation, a side film-based encapsulation, and a bottom film-based encapsulation;
degassing the top insulation layer, the side insulation layer, and the bottom insulation layer, wherein the top insulation layer, the side insulation layer, and the bottom insulation layer are degassed by at least one of evacuation or heating;
forming a top joint, a side joint, and a bottom joint to encapsulate the top insulation layer, the side insulation layer, and the bottom insulation layer within respective of the top film-based encapsulation, the side film-based encapsulation, and the bottom film-based encapsulation; and
adhering a component package, an inner enclosure, the top film-based encapsulation, the side film-based encapsulation, and the bottom film-based encapsulation adhered within a cavity by an adhesive, wherein at least a lid of a process condition measurement device defines the cavity.

26. A method comprising:
placing a component package, an inner enclosure, a top insulation layer, a side insulation layer, and a bottom insulation layer within a multi-layer film-based encapsulation;
degassing the top insulation layer, the side insulation layer, and the bottom insulation layer, wherein the top insulation layer, the side insulation layer, and the bottom insulation layer are degassed by at least one of evacuation or heating;
forming a joint to encapsulate the component package, the inner enclosure, the top insulation layer, the side insulation layer, and the bottom insulation layer within the multi-layer film-based encapsulation; and
adhering the multi-layer film-based encapsulation within a cavity by an adhesive, wherein at least a lid of a process condition measurement device defines the cavity.
